(19) United States
(12) Patent Application Publication
(10) Pub. No.: US 2009/0057905 A1
(43) Pub. Date: Mar. 5, 2009

(54) Semiconductor Device and Method of Manufacturing the Same

(76) Inventor: Dong Yeal Keum, Icheon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 12/199,534

(22) Filed: Aug. 27, 2008

(30) Foreign Application Priority Data
Aug. 30, 2007 (KR) 10-2007-0087533

(51) Int. Cl. H01L 21/768; H01L 23/532

(52) U.S. Cl. 257/751; 438/643; 257/E23.161; 257/E21.584

(57) ABSTRACT

A metal interconnection layout for a semiconductor device and a method of manufacturing the semiconductor device are disclosed. The semiconductor device can maintain a minimum design rule and secure a distance between via holes to inhibit a metal bridge phenomenon from being generated. The semiconductor device comprises a substrate, an interlayer dielectric, a first metal interconnection, and a second metal interconnection parallel to the first metal interconnection. The interlayer dielectric can be disposed on the substrate. The first metal interconnection is connected to the substrate or lower interconnect through at least one first via hole in the interlayer dielectric. The second metal interconnection is adjacent to the first metal interconnection and can be connected to the substrate or another lower interconnect through at least one second via hole in the interlayer dielectric. The first via hole and the second via hole are staggered from each other along the first metal interconnection and the second metal interconnection, respectively.

### CROSS-REFERENCE TO RELATED APPLICATION

The present application claims the benefit under 35 U.S.C. §119 of Korean Patent Application No. 10-2007-0087533, filed Aug. 30, 2007, which is hereby incorporated by reference in its entirety.

### BACKGROUND

With the increasing use of information media such as computers, semiconductor devices are being remarkably developed in recent years. In terms of function, the semiconductor devices are required to meet mass storage capacity and data-processing ability, as well as high-speed operation. Responding to such requirements, manufacturing technologies for semiconductor devices are being rapidly developed with a focus on increasing integration, reliability, and response speed.

As the integration of a semiconductor device is increasing, the width and thickness of a metal interconnection are being scaled down. In addition, contact points connected to the semiconductor device are also scaled down. The scaled-down width, thickness, and contact points cause an increase of resistance, resulting in the decrease of a signal propagation speed of the device. Also, a reduced sectional area of the interconnection causes a large current density, causing a severe electromigration (EM) of the interconnection.

As the size of the semiconductor device becomes sub-micron or less, this phenomenon occurs more often, so that the performance and reliability of a metal interconnection formed of aluminum (Al) are greatly degraded. That is, the aluminum metal interconnection has serious limitations including an operating speed limitation due to a signal delay caused by the increased interconnection resistance and an open circuit due to the electromigration phenomenon.

Therefore, copper is widely used as the next-generation metal interconnection material. The metal interconnection using copper has improved device characteristics with respect to the operating speed, the resistance, and parasitic capacitance between metals. However, an etching characteristic of copper is very poor. Accordingly, a damascene process instead of a related art etching process is widely used to form copper metal interconnections.

According to a method of manufacturing a semiconductor device using the damascene process, a first etching process for forming a trench in a flat interlayer dielectric is performed to form an interconnection line. Thereafter, a copper metal is filled in the trench.

FIGS. 1A and 1B are cross-sectional views illustrating a process of forming an interconnection using a damascene process in a semiconductor device according to a related art.

Referring to FIG. 1A, a first lower interconnection 101 and a second lower interconnection 102 are formed on a semiconductor substrate (not shown).

An interlayer dielectric 105 is formed on the first lower interconnection 101 and the second lower interconnection 102. The interlayer dielectric 105 includes a first via hole 111 exposing a portion of the first lower interconnection 101 and a second via hole 112 exposing a portion of the second lower interconnection 102.

An anti-reflective coating 120 is formed on the interlayer dielectric 105 including the first and second via holes 111 and 112.

A photoresist layer is formed on the anti-reflective coating 120, and the photoresist layer is selectively exposed and developed to form photoresist patterns 151a and 151b. The photoresist patterns 151a and 151b are used for forming trenches 121 and 122 (See FIG. 1B) in the interlayer dielectric 105.

In the case where an etch layer (here, the interlayer dielectric 105), the anti-reflective coating 120, and the photoresist layer are stacked, the anti-reflective coating 120 minimizes a reflectance of the etch layer due to the two principles of phase shift cancellation and light absorption of the media itself due to the extinction coefficient according to a combination of the reflective index n of media. The phase shift cancellation is a phenomenon in which ultra violet (UV) light reflected from an interface between the photoresist layer and the anti-reflective coating 120 and ultra violet light reflected from the interlayer dielectric 105 undergo destructive interference and are substantially cancelled by a phase difference of about λ/2.

The first and second via holes 111 and 112 are filled with the anti-reflective coating 120. An upper surface of the anti-reflective coating 120 corresponding to the first and second via holes 111 and 112 often has a bent shape.

Thus, a top notching phenomenon of the photoresist patterns 151a and 151b occurs on the bent interface of the anti-reflective coating 120 due to the non-planar surface of the anti-reflective coating 120.

As a result, as illustrated in FIG. 1B, when the photoresist patterns 151a and 151b do not properly serve as an etch mask, a height of the interlayer dielectric 105 between the first via hole 111 and the second via hole 112 may be excessively reduced.

When a barrier layer 130 and a copper metal layer 140 are formed on the interlayer dielectric 105, including the first and second via holes 111 and 112 and the trenches 121 and 122, and then polished to form a copper metal interconnection, a metal bridge B may occur due to the interlayer dielectric 105 having a region of reduced height. In addition, a short between metal interconnections occurs due to the metal bride B to cause a device defect.

For example, when the metal interconnection is formed using a dual damascene process, a design rule of about 0.13 μm or less is applied. In this case, the design rule for a space between the metal interconnections uses a design rule of about 0.16 μm to about 0.20 μm or more. A minimum design rule is applied obtain an optimum layout when arranging a pattern layer. When the via holes are formed for the metal interconnection, a metal bridge B may occur because of the use of minimum design rule distance between via holes and metal lines when the via holes are arranged in a line.

### BRIEF SUMMARY

Embodiments provide a semiconductor device comprising a metal interconnection and a method of manufacturing the same. Particularly, the semiconductor device can maintain a minimum design rule and secure a distance between via holes while inhibiting a metal bridge phenomenon from being generated.

In one embodiment, a semiconductor device comprises: an interlayer dielectric on a substrate; a first metal interconnection connected to the substrate or a lower metal interconnection through at least one first via hole in the interlayer dielectric; and a second metal interconnection adjacent to the first metal interconnection, the second metal interconnection being connected to the substrate or another lower interconnection through at least one second via hole in the interlayer dielectric, wherein the first via hole and the second via hole are staggered from each other.

In another embodiment, a method of manufacturing a semiconductor device comprises: forming an interlayer dielectric on a substrate; forming at least one first via hole and at least one second via hole in the interlayer dielectric; forming a metal layer on the interlayer dielectric; and polishing the metal layer to form a first metal interconnection on the at least one first via hole and a second metal interconnection on the at least one second via hole, wherein the at least one first via hole is disposed along the first metal interconnection, the at least one second via hole is disposed along the second metal interconnection, and the first via hole and the second via hole are staggered from each other.

In a further embodiment, a semiconductor device can comprise: an interlayer dielectric on a substrate: a first metal interconnection in a first trench and corresponding at least one first via hole in the interlayer dielectric; and a second metal interconnection adjacently parallel to the first metal interconnection, the second metal interconnection being disposed in a second trench and corresponding at least one second via hole in the interlayer dielectric, wherein a size of the at least one second via hole is smaller than that of the at least one first via hole.

In a still further embodiment, a method of manufacturing a semiconductor device can comprise: forming an interlayer dielectric on a substrate; forming, in the interlayer dielectric, at least one first via hole, a first trench on the at least one first via hole, at least one second via hole having a size smaller than that of the first via hole, and a second trench on the at least one second via hole; forming a metal layer on the interlayer dielectric; and polishing the metal layer to form a first metal interconnection in the at least one first via hole and the first trench and a second metal interconnection in the at least one second via hole and the second trench.

Therefore, in a manufacturing process of a semiconductor device according to embodiments of the present invention, a minimum design rule can be maintained, and also, a distance between via holes can be secured to inhibit a metal bridge phenomenon from being generated.

The details of one or more embodiments are set forth in the accompanying drawings and the description below. Other features will be apparent from the description and drawings, and from the claims.

### BRIEF DESCRIPTION OF THE DRAWINGS

FIGS. 1A and 1B are cross-sectional views illustrating a process of forming an interconnection using a damascene process in a semiconductor device according to a related art.

FIG. 2 is a partial plan view of a semiconductor device according to an embodiment.

FIG. 3 is a cross-sectional view taken along lines I-I′ and II-II′ of FIG. 2.

FIGS. 4 to 12 are cross-sectional views illustrating a process of forming an interconnection in a semiconductor device according to an embodiment.

FIG. 13 is a partial plan view of a metal interconnection of a semiconductor device according to an embodiment.

FIG. 14 is a partial plan view of a metal interconnection of a semiconductor device according to an embodiment.

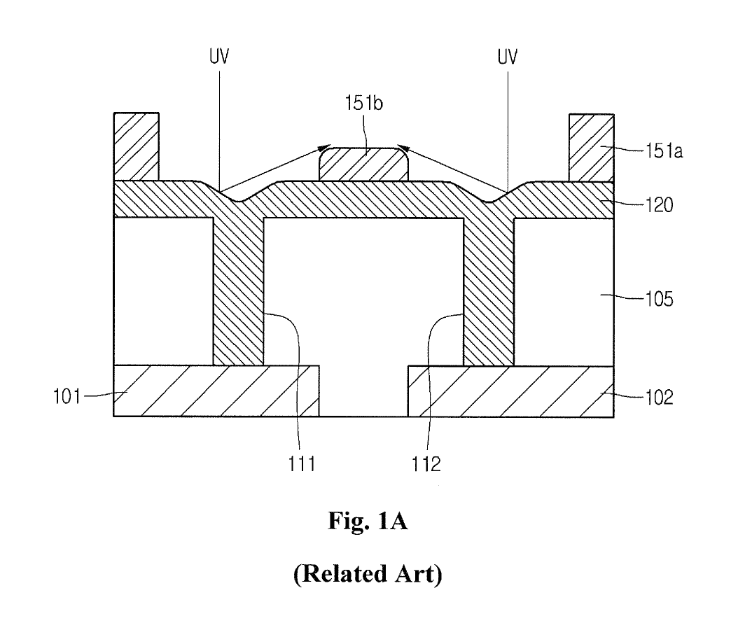

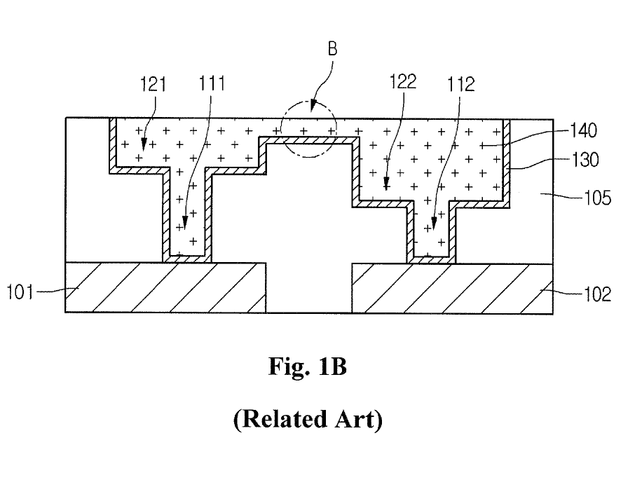

### DETAILED DESCRIPTION

Reference will be now made in detail to embodiments, examples of which are illustrated in the accompanying drawings. The invention may, however, be embodied in many different forms and should not be construed as being limited to the embodiments set forth herein; rather, these embodiments are provided so that this disclosure will be thorough and complete, and will fully convey the concept of the invention to those skilled in the art.

Embodiments of a metal interconnection for a semiconductor device and a method of manufacturing the same will be described in detail with reference to the accompanying drawings. It should be understood that when terms such as “first” and “second” are used to describe members, the members are not limited by these terms. For example, a plurality of members may be provided. Therefore, when the terms such as “first” and “second” are used, it will be apparent that a plurality of members may be provided. In addition, the terms “first” and “second” can be selectively or exchangeably used for the members. In the figures, a dimension of each of elements may be exaggerated for clarity of illustration, and the dimension of each of the elements may be different from an actual dimension of each of the elements. Not all elements illustrated in the drawings must be included and limited to the present disclosure, but the elements except essential features of the present disclosure may be added or deleted.

When the terms “on” or “over” are used herein, when referring to layers, regions, patterns, or structures, it is understood that the layer, region, pattern or structure can be directly on another layer or structure, or intervening layers, regions, patterns, or structures may also be present. When the terms “under” or “below” are used herein, when referring to layers, regions, patterns, or structures, it is understood that the layer, region, pattern or structure can be directly under the other layer or structure, or intervening layers, regions, patterns, or structures may also be present.

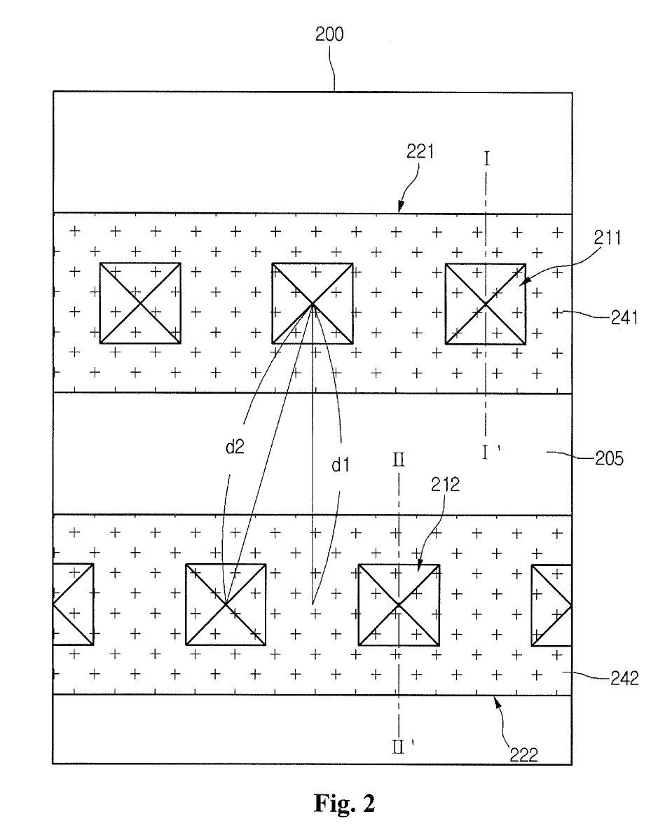

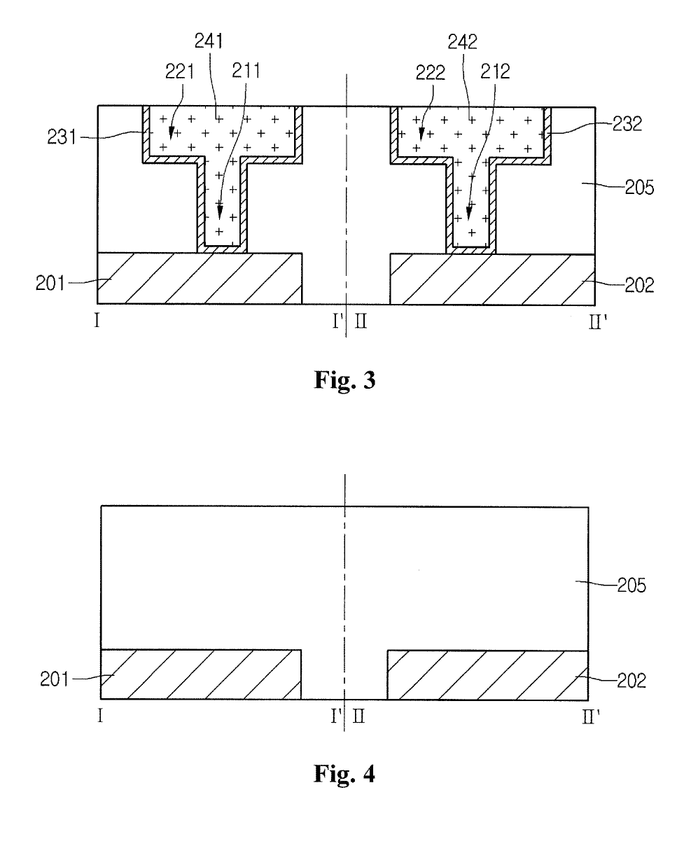

FIG. 2 is a partial plan view of a semiconductor device according to an embodiment, and FIG. 3 is a cross-sectional view taken along lines I-I′ and II-II′ of FIG. 2.

Referring to FIGS. 2 and 3, a first lower interconnection 201 and a second lower interconnection 202 can be formed on a semiconductor substrate 200. Although only a first lower interconnection 201 and a second lower interconnection 202 are illustrated, the present disclosure is not limited thereto. For example, other structures and interconnections may be further formed on the semiconductor substrate 200.

Also, the first and the second lower interconnections 201 and 202 may substantially have either an interconnection structure or a different structure. For example, the first and the second lower interconnections 201 and 202 can be a lower structure electrically connected to a metal interconnection to be formed using a damascene process.

The semiconductor substrate 200 can include a well and a bonding portion, a dielectric including a lower metal interconnection in a multilayer metal interconnection structure, and/or a conductive pattern used as an electrode of a semiconductor device.

An interlayer dielectric 205 covering the first and second lower interconnections 201 and 202 can be further formed on the semiconductor substrate 200.

The interlayer dielectric 205 can include a first via hole 211 exposing a portion of the first lower interconnection 201 and a second via hole 212 exposing a portion of the second lower interconnection 202.

The interlayer dielectric 205 includes a first trench 221 formed on the first via hole 211 and a second trench 222 formed on the second via hole 212.

According to an embodiment of the present invention, the first via hole 211 and the second via hole 212 are staggered from each other.

For example, when the first lower interconnection 201 is parallel to the second lower interconnection 202, the first via hole 211 formed along the first lower interconnection 201 is staggered with respect to the second via hole 212 formed along the second lower interconnection 202.

A distance d2 between the first via hole 211 and the second via hole 212, which are nearest to each other is greater than a distance d1 between two via holes if they were arranged in parallel along a line.

A first barrier layer pattern 231 and a first metal interconnection 241 can be formed in the first via hole 211 and the first trench 221.

A second barrier layer pattern 232 and a second metal interconnection 242 can be formed in the second via hole 212 and the second trench 222.

In an embodiment, the first and second metal interconnections 241 and 242 can include a copper metal interconnection.

In addition, the first and second barrier layer patterns 231 and 232 can be formed of at least one of Ti, Ta, TaN, TiN, TaSiN, and TiSiN.

FIGS. 4 to 12 are cross-sectional views illustrating a process of forming an interconnection in a semiconductor device according to an embodiment.

Referring to FIG. 4, a first lower interconnection 201 and a second lower interconnection 202 can be formed on a substrate (not shown).

The substrate can include any structures known in the art. For example, a well and a bonding portion can be formed on the substrate, a dielectric including a lower metal interconnection in a multilayer metal interconnection structure, can be formed on the substrate, and/or a conductive pattern used as an electrode of a semiconductor device can be formed on the substrate.

After forming the first and second lower interconnections 201 and 202, an interlayer dielectric 205 can be formed on the substrate.

In an embodiment, the interlayer dielectric 205 can include an oxide layer.

For example, the interlayer dielectric 205 can be formed of a material having a low dielectric constant such as fluorinated-silicate-glass (FSG) formed using a plasma enhanced chemical vapor deposition method.

The first lower interconnection 201 and the second lower interconnection 202 can be formed in parallel lines. However, embodiments are not limited thereto.

In addition, other semiconductor structures and interconnections, as well as the first and second lower interconnections 201 and 202, can be further formed on the substrate.

An etch stop layer can be formed on the substrate before forming the interlayer dielectric 205. The etch stop layer can include a silicon nitride (SiN) layer. The etch stop layer can be used to protect the substrate from damage due to etching of the interlayer dielectric 205.

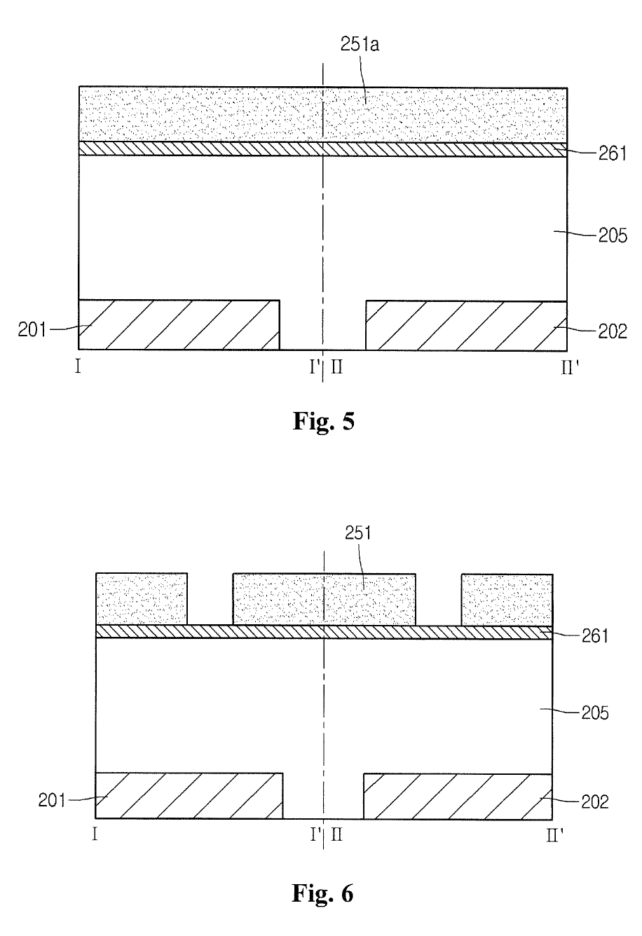

Referring to FIG. 5, a first anti-reflective coating 261 can be formed on the interlayer dielectric 205, and a first photoresist layer 251a can be formed on the first anti-reflective coating 261.

Referring to FIG. 6, the first photoresist layer 251a can be selectively exposed and developed to form a first photoresist pattern 251 on the interlayer dielectric 205.

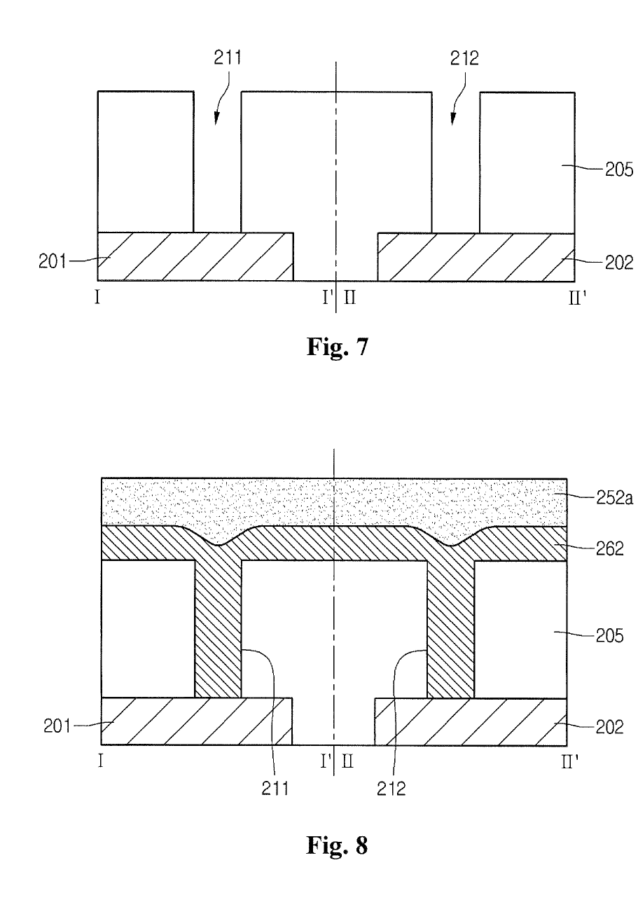

Referring to FIG. 7, the first anti-reflective coating 261 and the interlayer dielectric 205 can be etched using the first photoresist pattern 251 as an etch mask to form at least one first via hole 211 and at least one second via hole 212.

The first and second via holes 211 and 212 expose targets which will be electrically connected thereto, e.g., portions of the first and second lower interconnections 201 and 202, respectively.

The first anti-reflective coating 261 and the first photoresist pattern 251 can then be removed.

Referring to FIG. 8, a second anti-reflective coating 262 and a second photoresist layer 252a can be formed on the interlayer dielectric 205 including the first and second via holes 211 and 212.

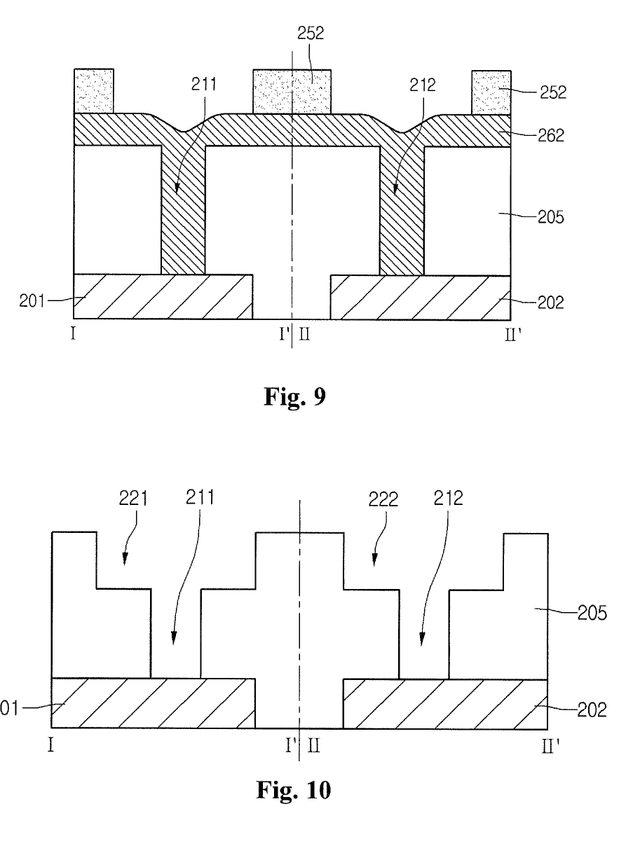

Referring to FIG. 9, the second photoresist layer 252a can be selectively exposed and developed to form a second photoresist pattern 252 on the interlayer dielectric 205.

Since the first and second via holes 211 and 212 are staggered on a surface of the substrate, a distance between the first via hole 211 and the second via hole 212 becomes wider.

Thus, the effect of a bent degree of an upper surface of the second anti-reflective coating 262 is reduced, and the upper surface of the second anti-reflective coating 262 is flat at the region adjacent to each via hole such that the anti-reflective coating 262 is inhibited from causing diffuse reflection. Also, effective phase shift cancellation of light irradiated from the second photoresist layer is caused to uniformly form the second photoresist pattern 252.

Referring to FIG. 10, portions of the second anti-reflective coating 262 and the interlayer dielectric 205 are etched using the second photoresist pattern 252 as an etch mask to respectively form first and second trenches 221 and 222 on the first and second via holes 211 and 212.

Thereafter, the second photoresist pattern 252 and the second anti-reflective coating 262 can be removed.

In certain embodiments, the first and second via holes 211 and 212 and the first and second trenches 221 and 222 can be formed by performing a plasma etching process on the interlayer dielectric 205. Fluorine (F)-based gas (e.g., CF₄) can be used for the plasma etching process, and CO, oxygen (O), or a mixture thereof can be used for the plasma etching process.

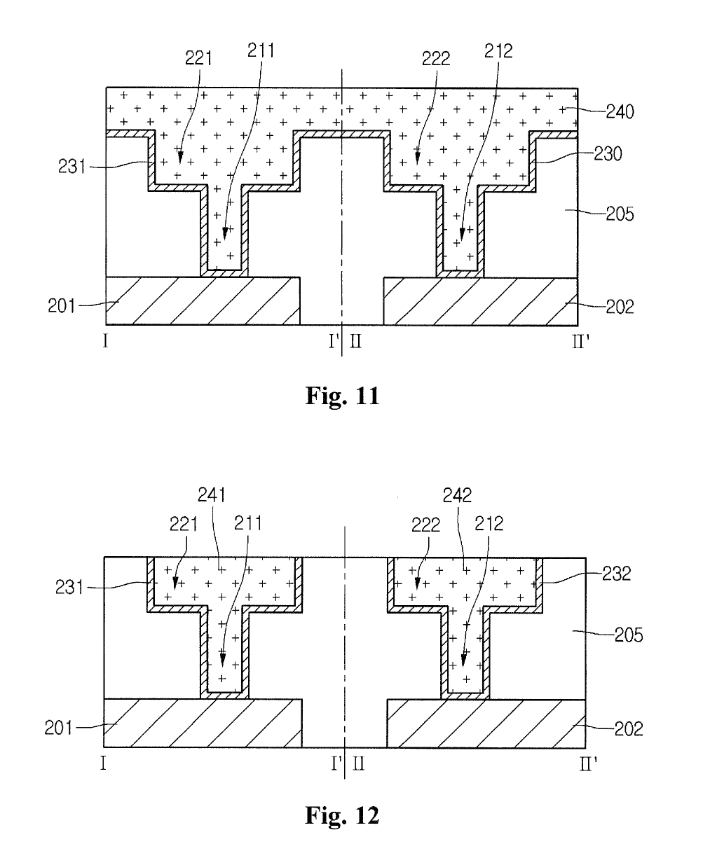

Referring to FIG. 11, a barrier layer 230 can be formed on the interlayer dielectric 205 including the first and second via holes 211 and 212 and the first and second trenches 221 and 222.

The barrier layer 230 can be formed of, for example, at least one of Ti, Ta, TaN, TiN, TaSiN, and TiSiN.

The barrier layer 230 can include a single layer or a multilayer.

A seed layer can be formed on the barrier layer 230. In certain embodiments, the seed layer can be formed of at least one material selected from the group consisting of Al, Cu, Ti, and Ta.

A copper metal layer 240 can be formed on the interlayer dielectric 205 including the seed layer.

The copper metal layer 240 can be formed using an electroplating method, a physical vapor deposition (PVD) method, or a chemical vapor deposition (CVD) method.

Referring to FIG. 12, the copper metal layer 240 and barrier layer 230 can be planarized to form a first metal interconnection 241 in the first via hole 211 and the first trench 221 and a second metal interconnection 242 in the second via hole 212 and the second trench 222.

In one embodiment, a chemical mechanical polishing (CMP) process can be performed to form barrier layer patterns 231 and 232 and metal interconnections 241 and 242 in the first and second via holes 211 and 212 and the first and second trenches 221 and 222. Since portions of the barrier layer 230 and the seed layer formed on the interlayer dielectric 205 are removed together by performing the CMP process, an upper surface of the interlayer dielectric 205 except a region in which the copper metal interconnection is formed is exposed.

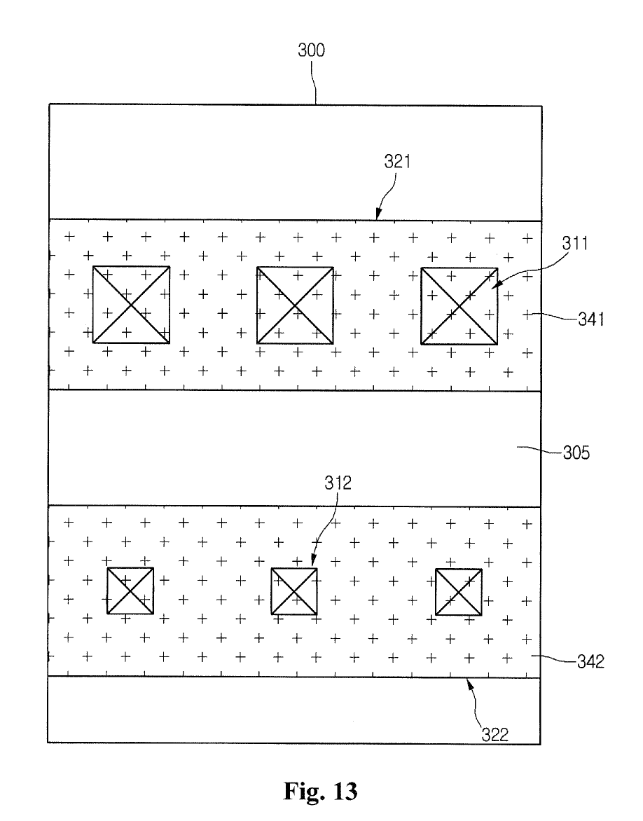

FIG. 13 is a partial plan view of a via and metal interconnection layout for a semiconductor device according to an embodiment.

Referring to FIG. 13, a first metal interconnection 341 disposed in a first via hole 311 and a first trench 321 can be formed on a semiconductor substrate 300 including an interlayer dielectric 305.

A second metal interconnection 342 disposed in a second via hole 312 and a second trench 322 can also be formed in the interlayer dielectric 305.

The first metal interconnection 341 and the second metal interconnection 342 can be spaced a predetermined distance from each other.

The first metal interconnection 341 can be connected to a first lower interconnection (not shown) through the first via hole 311, and the second metal interconnection 342 can be connected to a second lower interconnection (not shown) through the second via hole 312.

According to one embodiment, as shown in FIG. 13, a size of the second via hole 312 is smaller than that of the first via hole 311.

When any one of the first via hole 311 and the second via hole 312 is smaller in size, a distance between the first via hole 311 and the second via hole 312 can become greater compared to when the first and second via holes 311 and 312 have the same size. This is even the case for when the via holes 311 and 312 align along the line of the metal interconnections 341 and 342.

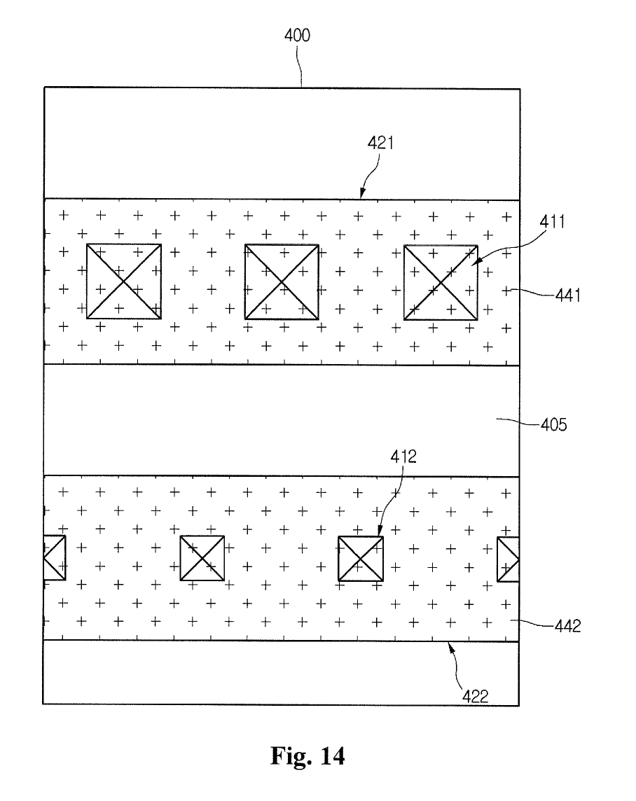

FIG. 14 is a partial plan view of a semiconductor device according to a further embodiment.

Referring to FIG. 14, a first metal interconnection 441 disposed in a first via hole 411 and a first trench 421 can be formed in an interlayer dielectric 405 on a substrate 400.

A second metal interconnection 442 disposed in a second via hole 412 and a second trench 422 can also be formed disposed in the interlayer dielectric 405.

The first metal interconnection 441 and the second metal interconnection 442 can be spaced a predetermined distance from each other.

The first metal interconnection 441 can be connected to a first lower interconnection (not shown) through the first via hole 411, and the second metal interconnection 442 can be connected to a second lower interconnection (not shown) through the second via hole 412.

According to an embodiment, as shown in FIG. 15, the size of the second via hole 412 is smaller than that of the first via hole 411, and second via holes 411 and 412 are staggered from each other. Therefore, a minimum design rule of the distance between the metal interconnections can be maintained, and the distance between via holes 411 and 412 can be secured to inhibit the metal bridge phenomenon from being generated.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
an interlayer dielectric on a substrate:
a first metal interconnection connected to a first lower target on the substrate through at least one first via hole in the interlayer dielectric; and
a second metal interconnection adjacent to the first metal interconnection, the second metal interconnection being connected to a second lower target on the substrate through at least one second via hole in the interlayer dielectric,
wherein the first via hole and the second via hole are arranged staggered from each other.

2. The semiconductor device according to claim 1, wherein the interlayer dielectric further comprises a first trench disposed on the first via hole and a second trench disposed on the second via hole.

3. The semiconductor device according to claim 2, wherein the first metal interconnection is disposed in the first trench, and the second metal interconnection is disposed in the second trench.

4. The semiconductor device according to claim 3, further comprising a barrier layer pattern under the first metal interconnection in the first via hole and the first trench and under the second metal interconnection in the second via hole and the second trench.

5. The semiconductor device according to claim 4, wherein the barrier layer pattern is formed of at least one of Ti, Ta, TaN, TiN, TaSiN, and TiSiN.

6. The semiconductor device according to claim 2, wherein the first trench and the second trench are adjacently parallel to each other.

7. The semiconductor device according to claim 1, wherein a size of the second via hole is smaller than that of the first via hole.

8. The semiconductor device according to claim 1, wherein the first metal interconnection and the second metal interconnection comprise copper metal interconnections.

9. A method of manufacturing a semiconductor device, comprising:
forming an interlayer dielectric on a substrate;
forming at least one first via hole and at least one second via hole in the interlayer dielectric;
forming a metal layer on the interlayer dielectric; and
polishing the metal layer to form a first metal interconnection on the at least first via hole and a second metal interconnection on the at least second via hole,
wherein the at least one first via hole and the at least one second via hole are staggered from each other along the first metal interconnection and the second metal interconnection, respectively.

10. The method according to claim 9, wherein the first metal interconnection and the second metal interconnection are parallel to each other.

11. The method according to claim 9, wherein a size of the second via hole is smaller than that of the first via hole.

12. The method according to claim 9, further comprising etching a portion of the interlayer dielectric to form a first trench on the at least one first via hole and a second trench on the at least one second via hole.

13. The method according to claim 12, wherein the forming of the first trench and the second trench comprises:
forming an anti-reflective coating on the interlayer dielectric, including in the at least one first via hole and the at least one second via hole;
forming a photoresist layer on the anti-reflective coating;
selectively exposing and developing the photoresist layer to form a photoresist pattern exposing the at least one first via hole and the at least one second via hole and a portion of the interlayer dielectric; and
etching the interlayer dielectric using the photoresist pattern as an etch mask.

14. The method according to claim 9, wherein the metal layer comprises copper.

15. The method according to claim 9, further comprising, before the forming of the metal layer on the interlayer dielectric, depositing a barrier layer on an entire surface of the interlayer dielectric including the at least one first via hole and the at least one second via hole.

16. The method according to claim 15, wherein the barrier layer is formed of at least one of Ti, Ta, TaN, TiN, TaSiN, and TiSiN.

17. The method according to claim 9, further comprising, before the forming of the metal layer on the interlayer dielectric, forming a seed layer on an entire surface of the interlayer dielectric including the at least one first via hole and the at least one second via hole, wherein the seed layer is formed of at least one material selected from the group consisting of Al, Cu, Ti, and Ta.

18. A semiconductor device comprising:
an interlayer dielectric on a substrate, the interlayer dielectric comprising at least one first via hole, a first trench on the at least one first via hole, at least one via second via hole, and a second trench on the at least one second via hole:
a first metal interconnection in the first trench and the at least one first via hole; and
a second metal interconnection adjacently parallel to the first metal interconnection, the second metal interconnection being disposed in the second trench and the at least one second via hole,
wherein a size of the second via hole is smaller than that of the first via hole.

19. The semiconductor device according to claim 18, wherein the at least one first via hole is disposed along the first metal interconnection, the at least one second via hole is disposed along the second metal interconnection, and the first via hole and the second via hole are arranged staggered from each other.

20. A method of manufacturing a semiconductor device, comprising:
forming an interlayer dielectric on a substrate;
forming at least one first via hole in the interlayer dielectric and a first trench on the at least one first via hole;
forming at least one second via hole having a size smaller than that of the first via hole and a second trench on the at least one second via hole;
forming a metal layer on the interlayer dielectric; and
polishing the metal layer to form a first metal interconnection in the at least one first via hole and the first trench and a second metal interconnection in the at least one second via hole and the second trench.
